(19) United States
(12) Patent Application Publication
(10) Pub. No.: US 2015/0008400 A1
(43) Pub. Date: Jan. 8, 2015

(54) ORGANIC LIGHT EMITTING DISPLAY DEVICES AND METHODS OF MANUFACTURING ORGANIC LIGHT EMITTING DISPLAY DEVICES

(71) Applicant: Samsung Display Co., LTD., Yongin-City (KR)

(72) Inventor: Jong-Seok KIM, Yongin-si (KR)

(73) Assignee: Samsung Display Co., LTD., Yongin-City (KR)

(21) Appl. No.: 14/267,782

(22) Filed: May 1, 2014

(30) Foreign Application Priority Data
Jul. 8, 2013 (KR) 10-2013-0079447

(51) Int. Cl. H01L 51/52; H01L 51/56; H01L 27/32

(52) U.S. Cl. CPC H01L 51/5228; H01L 27/3279; H01L 51/56
USPC 257/40; 438/34

(57) ABSTRACT

An inter-layer bridging connection is provided in an organic light emitting display and a method of manufacturing the same is provided. The organic light emitting display device is subdivided into a major interior, first region I, an auxiliary power coupling region II and a peripheral power line region III where the second region (II) extends at least partially around the first region, and the third region (III) extends at least partially around the second region. Additionally, the display device includes a substrate, a first electrode, a second electrode, an interposed light emitting structure, a power line, a conductive pattern and an auxiliary electrode. The first electrode and the light emitting structure are both disposed in the first region. The power line is disposed in the third region. The second electrode is at least partially transparent and is disposed in the first region and extends into the second region (II). The conductive pattern electrically connects the second electrode with the power line. The auxiliary electrode has reduced resistivity per unit area and directly contacts the second electrode. The auxiliary electrode is disposed in the second region.

### CROSS-REFERENCE TO RELATED APPLICATION

This application claims priority under 35 USC §119 to Korean Patent Application No. 10-2013-0079447 filed on Jul. 8, 2013 in the Korean Intellectual Property Office (KIPO), the entire disclosure of which application is incorporated herein by reference.

### BACKGROUND

1. Field

The present disclosure of invention relates to organic light emitting display devices and a method of manufacturing such organic light emitting display devices. Particularly, example embodiments relate to an organic light emitting display device having an improved light emission uniformity and a method of manufacturing the same.

2. Description of Related Technology

Particularly, among the flat or otherwise thin panel display devices, an organic light emitting display device (OLEDD) displays an image by using organic light emitting diodes as emission devices. The organic light emitting display device warrants attention as a next generation display device because of its excellent brightness and color purity.

A typical organic light emitting diode (OLED) includes an anode electrode and a cathode electrode that face each other and an organic light emitting layer interposed therebetween. At least one of the anode and cathode electrodes is composed of a light-passing conductive material so that the generated light can be output. During the light emission operation of the organic light emitting diode, the anode electrode is connected to a relatively high voltage node for providing pixel power, and the cathode electrode is connected to a relatively low potential pixel power node. As a result, relatively large currents (I=V/R) may flow. More specifically, holes and electrons are respectively injected into the organic light emitting layer from the anode electrode and the cathode electrode, respectively. The electrons join with the holes in the organic light emitting layer to thereby excite molecules to high energy states. As the excited molecules return to their more normal and lower energy states, they emit energy in the form of photons, and the organic light emitting diode thereby emits light.

In a typical general organic light emitting display device (OLEDD), the anode electrode and the cathode electrode of the respective organic light emitting diode (OLED) are formed to cover whole area of the corresponding pixel unit.

When the anode electrode is connected to high potential pixel power source via a pixel switching circuit, and the cathode electrode is connected directly to the low potential pixel power without it being controlled by current passing through the pixel circuit, the cathode electrode may be formed on a whole pixel unit. The cathode electrode is connected to connection wirings such as bus lines of the low potential pixel power around the pixel unit, and is supplied with the low potential pixel power.

In order to reduce dead space (in other words, in order to increase the light emitting aperture ratio of each pixel unit), a reduction is desired for a cathode contact region and a bus region in which the cathode electrode and the bus lines of the low potential pixel power are connected to the low potential pixel power. However, brightness within the pixel unit may not be uniform due to current times resistance (I*R) drops developed between the source of the low potential pixel power and the points where it is applied to the light emitting layer by way of the conductive material of the cathode electrode.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding invention dates of subject matter disclosed herein.

### SUMMARY

Disclosed is an organic light emitting display device having an improved light emitting uniformity.

Methods of manufacturing various embodiments of the organic light emitting display device having improved light emitting uniformity are also disclosed.

According to an example embodiment, there is provided an organic light emitting display device including a substrate, a first electrode, a light emitting structure, a power line, a second electrode, a conductive pattern and an auxiliary electrode. The substrate is subdivided into a first region (I), a second region (II) and a third region (III). The second region surrounds the first region, and the third region surrounds the second region. The first electrode and the light emitting structure are both disposed in the first region and on the substrate. The power line is disposed in the third region and on the substrate. The second electrode opposes the first electrode. The second electrode is at least partially transmissive of light and is disposed in the first region of the substrate while also extending into the second region. The conductive pattern electrically connects the second electrode with the power line. The auxiliary electrode directly contacts the second electrode. The auxiliary electrode is disposed in the second region of the substrate.

In some example embodiments, the auxiliary electrode has a thickness substantially larger than a thickness of the second electrode.

In some example embodiments, the auxiliary electrode includes a material substantially the same as a material used in the second electrode.

In some example embodiments, the auxiliary electrode entirely covers a top surface of a portion of the second electrode in the second region.

In some (alternate) example embodiments, the second electrode entirely cover a top surface of the auxiliary electrode in the second region.

In some example embodiments, the second electrode includes an alloy of magnesium and silver having a respective by weight ratio of about 9:1.

In some example embodiments, the power line surrounds at least three sides of the second region.

In some example embodiments, the organic light emitting display device further includes a light blocking pixel defining pattern disposed between the second electrode and the conductive pattern in the second region. The pixel defining pattern may cover end portions of the conductive pattern.

In the example embodiments, the first region (I) functions as an image displaying region that contains the light emitting structure, while the second region and the third region are non-displaying regions.

According to example embodiments, there is provided a method of manufacturing an organic light emitting display device. In the method, a substrate having a first region, a second region and a third region is provided. The second region surrounds the first region, and the third region surrounds the second region. A power line is formed in the third region on the substrate. A first electrode and a conductive pattern are formed simultaneously. The first electrode is disposed in the first region of the substrate. A light emitting structure is formed on the first electrode. An auxiliary electrode is formed to be electrically connected to the conductive pattern in the second region by performing a deposition process using a first mask. A second electrode opposing the first electrode is formed by performing a deposition process using a second mask. The second electrode is disposed in the first region of the substrate and being electrically connected to the auxiliary electrode.

In example embodiments, the first mask may be arranged to partially expose the second region of the substrate, and the second mask may be arranged to expose the first region and the second region of the substrate.

In example embodiments, the deposition processes using the first mask and the second mask may include a physical vapor deposition process.

In example embodiments, a process for forming the auxiliary electrode and a process for forming the second electrode may be performed in the same chamber using the same source gas.

In example embodiments, the power line may surround at least three sides of the second region.

In example embodiments, the auxiliary electrode may have a thickness substantially larger than a thickness of the second electrode.

In example embodiments, a pixel defining pattern may be further formed in the second region, before forming the light emitting structure.

In example embodiments, the first region may be an image displaying region that contains the light emitting structure, and the second region and the third region are non-displaying regions.

According to example embodiments, an organic light emitting display device may include a second electrode disposed in a first region I and a second region II, a power line disposed in the third region III and a conductive pattern disposed in the second region II and the third region III. The organic light emitting display device may further include an auxiliary electrode in the second region II between the conductive pattern and the second electrode. Therefore, the low potential pixel power ELVSS may be transferred from the power line to the second electrode through the conductive pattern and the auxiliary electrode without incurring a substantially I*R voltage drop. The auxiliary electrode may have a relatively lower resistivity per unit area than that of the second electrode so that the I*R voltage drop for coupling the low potential pixel power ELVSS to the light emitting structure may be reduced. Further, the auxiliary electrode may be disposed in the second region II, and may not disposed in the first region I, so that the light output efficiency of the organic light emitting display device may not be degraded. Therefore, the light emission uniformity of the organic light emitting display device may be improved.

### BRIEF DESCRIPTION OF THE DRAWINGS

The present teachings will be more clearly understood from the following detailed description taken in conjunction with the accompanying drawings. FIGS. 1 to 21 represent non-limiting, example embodiments as described herein:

FIG. 1 is a block diagram illustrating a circuit structure of an organic light emitting display device in accordance with some embodiments;

FIG. 2 is a top plan view illustrating an organic light emitting display device in accordance with a first embodiment;

FIG. 3 is a local cross-sectional view illustrating an organic light emitting display device in accordance with the first embodiment and taken according to line V-V′ of FIG. 2;

FIG. 4 is a local cross-sectional view illustrating an organic light emitting display device in accordance with another embodiment;

FIG. 5 is a local cross-sectional view illustrating an organic light emitting display device in accordance with yet another embodiment;

FIGS. 6 to 13 are plan views and cross-sectional views illustrating a method of manufacturing an organic light emitting display device in accordance with some of the embodiments;

FIGS. 14 to 17 are plan views and cross-sectional views illustrating a method of manufacturing an organic light emitting display device in accordance with yet others of the embodiments; and

FIGS. 18 to 21 are plan views and cross-sectional views illustrating a method of manufacturing an organic light emitting display device in accordance with other embodiments.

### DETAILED DESCRIPTION

Various example embodiments will be described more fully hereinafter with reference to the accompanying drawings, in which some example embodiments are shown. The present disclosure of inventive concept may, however, be embodied in many different forms and should not be construed as limited to the example embodiments set forth herein. Rather, these example embodiments are provided so that this disclosure will be thorough and complete, and will fully convey the scope of the present inventive concepts to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present teachings. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure most closely pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

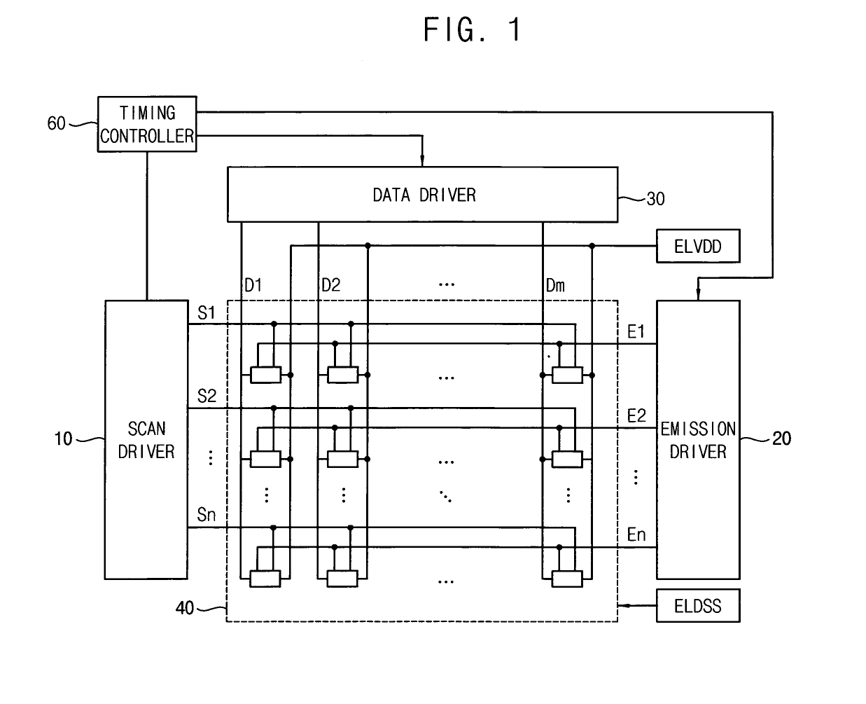

FIG. 1 is a block diagram illustrating a circuit structure of an organic light emitting display device in accordance with some of the here disclosed embodiments.

Referring to FIG. 1, the organic light emitting display device may include a scan lines driver 10, a light emission lines driver 20, a data lines driver 30, a pixels array unit 40, and a timing controller 60.

The scan lines driver 10 may be controlled by the timing controller 60, and may sequentially supply scan signals to scan lines S1 to Sn that extend through the pixels array unit 40. Pixel rows may be selected by the scan signals, and may sequentially receive data signals.

The light emission lines driver 20 may be controlled by the timing controller 60, and may sequentially supply light control signals to light emission control lines E1 to En. The pixels may be controlled by the light emission control signals, and emit light accordingly.

The scan lines driver 10 and the light emission lines driver 20 may be mounted on a display panel (e.g., a common substrate) together with driving devices included in the pixels array unit 40 to thereby form a monolithically integrated built-in-circuit. Alternatively, the scan lines driver 10 and/or the light emission lines driver 20 may be mounted in the form of monolithically integrated chips to form a build-in-circuit.

In one class of embodiments, the scan lines driver 10 and the light emission lines driver 20 may be disposed on opposite sides of the panel while the pixels array unit 40 is interposed therebetween as is schematically shown in FIG. 1. Arrangement of the scan lines driver 10 and the light emission lines driver 20 is not limited to this arrangement.

For example, the scan lines driver 10 and the light emission lines driver 20 may be formed on a same side of the pixels array unit 40. Alternatively, both of the scan lines driver 10 and the light emission lines driver 20 may be formed on both sides of the pixel s array unit 40, respectively.

In addition, the light emission lines driver 20 may be omitted according to the configuration of the pixels that are provided in the pixels array unit 40.

The pixels array unit 40 may include a plurality of pixels 50. The pixels may be positioned at intersecting positions of scan lines S1 to Sn, light emission control lines E1 to En, and data lines D1 to Dm. The data lines driver 30 may be controlled by the timing controller 60, and supply data signals to the data lines D1 to Dm. The data signals supplied to the data lines D1 to Dm may be supplied to a row of pixels that are selected by the scan signals whenever a row-activating scan signal is respectively supplied to that row. The selected pixels may be charged to respective luminance-controlling voltages corresponding to the data signals.

The above-mentioned pixels array unit 40 may be supplied with high potential pixel power ELVDD and low potential pixel power ELVSS from the outside. The pixels array unit 40 may transfer the high potential pixel power ELVDD and the low potential pixel power ELVSS to the respective pixels. The respective pixels may emit light at respective brightnesses corresponding to the supplied data signal to display a desired image.

Each of the pixels may include an organic light emitting structure (not shown in FIG. 1) having a first electrode and a second electrode. At least one of these first and second electrodes is composed of a light-passing conductive material (e.g., ITO or IZO). The high potential pixel power ELVDD may be transferred to a first electrode 180 (see FIG. 3) of an organic light emitting structure in a selected pixel for an emission period of the selected pixel 50. The low potential pixel power ELVSS may be transferred to one or more connection points of the second electrode 220 (see FIG. 3) of the organic light emitting structure.

In one embodiment, the whole first electrodes 180 of the organic light emitting structures is formed as an opaque and metallic layer on an underside of the pixels array unit 40. On the other hand, the second electrodes 220 of the organic light emitting structures are formed of a light-passing and conductive material disposed on the topside of the whole pixels array unit 40.

Particularly, when the first electrodes 180 of the organic light emitting structures are connected to the high potential pixel power ELVDD via the pixel circuits and the second electrodes 220 of the organic light emitting structures are electrically connected to the low potential pixel power ELVSS without passing through the pixel circuits, the second electrode 220 of the organic light emitting structure may be formed on the light emitting upper side of the whole pixels array unit 40.

The above-mentioned second electrodes 220 may be supplied with the low potential pixel power ELVSS through wirings such as bus lines (not shown) formed around the pixels array unit 40.

The first electrodes 180 of the organic light emitting structures may be patterned so as to correspond to a pixels array within the pixels array unit 40.

The timing controller 60 may generate control signals in response to a synchronizing signal supplied from the outside. The generated control signals may be transmitted to the scan lines driver 10, the light emission lines driver 20, and the data lines driver 30. By such operations, the timing controller 60 may control the scan lines driver 10, the light emission lines driver 20, and the data lines driver 30. In addition, the timing controller 60 may deliver data fed from the outside to the data lines driver 30. The data lines driver 30 may generate respective data signals corresponding to the delivered data.

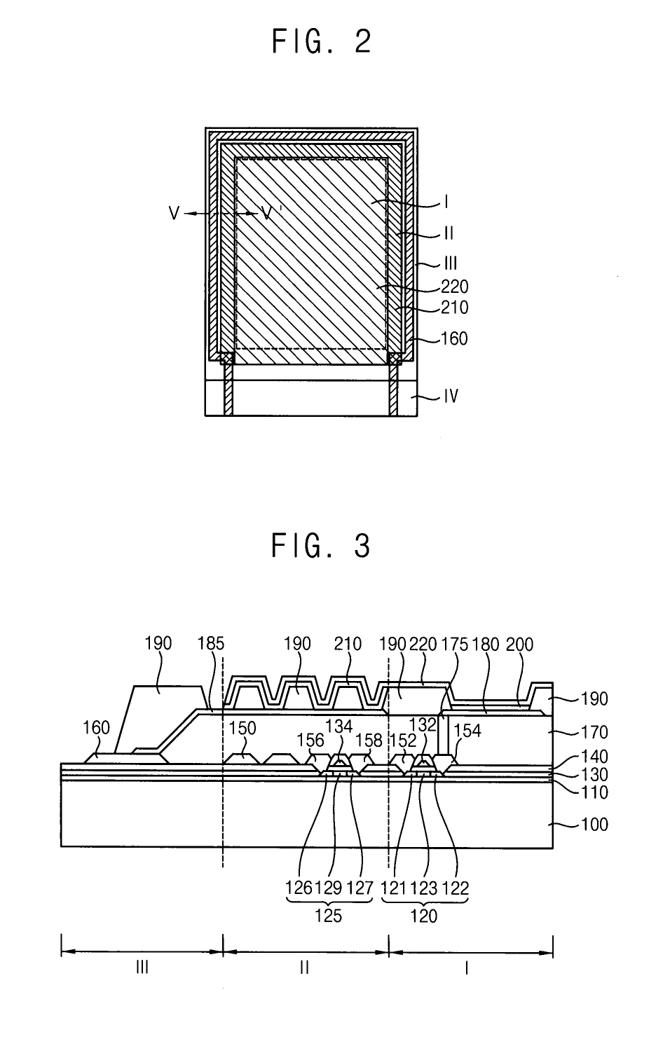

FIG. 2 is a plan view illustrating an organic light emitting display device in accordance with a first embodiment. FIG. 3 is a local cross-sectional view cut along a line V-V′ of FIG. 2.

Referring to FIG. 2, the organic light emitting display device, particularly a substrate 100, may be divided into a first region I, a second region II, a third region III and a fourth region IV. The first region I is also referred to herein as the major interior region I. The second region II is also referred to herein as the auxiliary coupling region II. The third region III is also referred to herein as the peripheral power line region III. The fourth region IV is also referred to herein as the bus lines conduit region IV.

More specifically, in the here described example embodiments, the first region I (major interior region I) may be a light emitting or display region in which one or more pixels are disposed. The first region I having a relatively large area may be disposed at a center of the structure shown in FIG. 2. Each of the pixels within this structure may include a respective light emitting structure respectively having a first electrode, a second electrode and an organic light emitting layer. When the organic light emitting display device is an active matrix type, each of the pixels may further include a switching structure such as a thin film transistor (TFT), and the switching structure may electrically contact the light emitting structure. The detailed constitution of the pixels will be described with reference to FIG. 3 as follows.

The second region II (auxiliary coupling region II) functions as a contact bridging region such that a conductive pattern is disposed to electrically connect the second electrode of the light emitting structure with a power line (160) of a different layer for thereby supplying the low potential pixel power ELVSS. The second region II may extend around at least one side of the first region I. For example, the second region II may surround three or more sides of the first region I. In one embodiment, test circuits and driving circuits such as a scan lines driver, emission lines driver, and the like may be disposed in the second region II (also additionally references herein as a non-displaying peripheral region II as well as being the auxiliary power coupling region II).

The yet more peripheral third region III may be a bus region where the power line (160) for supplying the low potential pixel power ELVSS is disposed. The third region III may extend around at least one side of the second region II. For example, the third region III may surround three or more sides of the second region II.

In one set of example embodiments, the second region II and the third region III may correspond to non-display peripheral regions of the whole of the display panel.

Further, the fourth region IV may be yet another peripheral region where one or more integrated circuit (IC's) chips are mounted or monolithically integrally disposed, these including the data lines driver and a plurality of pads for receiving a signal from outside. The fourth region IV may contact one side of the third region III. For example, the fourth region IV may contact a bottom side of the third region III as is shown in FIG. 2.

Referring to FIG. 3, the organic light emitting display device may include a base substrate 100 (shown as being at a lowest level of a multi-layered structure), a first switching structure, a second switching structure, a power line 160 (shown as being at a relatively low but not lowest level of the multi-layered structure), a first electrode 180, a conductive pattern 185, a organic light emitting layer 200, an auxiliary electrode 210 and a second electrode 220 (shown as being at a relatively high if not a highest level of the multi-layered structure). The organic light emitting display device, particularly the substrate 100, may be divided into the aforementioned first region I (major interior region I), second region II (auxiliary power coupling region II) and third region III (peripheral power line region III).

The first switching structure may be disposed in a layer between the base substrate 100 and an overlying first electrode 180 in the first region I. The light emitting layer 200 may be disposed in the first region I between the first electrode 180 and an overlying second electrode 220. The power line 160 (which is disposed at a relatively low layer) and the second electrode 220 (which is disposed at a relatively higher up layer) may be electrically connected to each other by an inter-layer bridging network including the conductive pattern 185 and an auxiliary electrode 210.

The base substrate 100 may be composed of a transparent insulating material. For example, the substrate 100 may include a glass substrate, a quartz substrate, a transparent resin substrate, and the like. In other example embodiments, the substrate 100 may be a flexible substrate.

A buffer layer 110 may be disposed on the substrate 100. The buffer layer 110 may prevent undesirable impurities (contaminants, e.g., moisture, oxygen, etc.) from diffusing from the substrate 100 into parts of the device that may be damaged by such impurities. The buffer layer 110 may also provide a flat top surface.

When the organic light emitting display device is of an active matrix type, the first switching structure may be disposed in the first region I on the substrate 100. In example embodiments, the first switching structure may include a first thin film transistor (TFT1) having a semiconductive pattern including one of amorphous silicon or a crystallized silicon. Alternatively, the first switching structure may include a thin film transistor having a semiconductive pattern including a semiconductive metal oxide such as an indium gallium zinc oxide (InGaZnO).

In example embodiments, the first switching structure may include a first semiconductor pattern 120, a gate insulation layer 130, a first gate electrode 132, a first source electrode 152, a first drain electrode 154, and the like.

The first semiconductor pattern 120 may be disposed on the buffer layer 110, and the gate insulation layer 130 may be disposed on the buffer layer 110 to cover the first semiconductor pattern 120. The first semiconductor pattern 120 may include a first source region 121, a first drain region 122 and a first channel region 123.

In example embodiment, the first semiconductor pattern 120 may include polysilicon, doped polysilicon, amorphous silicon or doped amorphous silicon. These may be used alone or in combinations. In other example embodiments, the first semiconductor pattern 120 may include a ternary system or a quaternary system semiconductive oxide comprising a combination of AwBxCyOz (where A, B, C—Zn, Cd, Ga, In, Sn, Hf or Zr; 0≦w, x, y; 0.01≦z≦0.1). For example, the first semiconductor pattern 120 may include aluminum zinc oxide (AlZnO), aluminum zinc tin oxide (AlZnSnO), gallium zinc tin oxide (GaZnSnO), indium gallium oxide (InGaO), indium gallium zinc oxide (InGaZnO), indium tin zinc oxide (InSnZnO), indium zinc oxide (InZnO), hafnium indium zinc oxide (HfInZnO) or zirconium tin oxide (ZnSnO). Further, the gate insulation layer 130 may include an oxide or an organic insulation material.

The first gate electrode 132 may be disposed on the gate insulation layer 130 adjacent to the first semiconductor pattern 120. For example, the first gate electrode 132 may overlap with the first channel region 123 of the first semiconductor pattern 120. The first gate electrode 132 may include a metal, a metal nitride, a conductive metal oxide, a transparent conductive material, and the like.

In example embodiments, a gate line disposed on the gate insulation layer 130 may be electrically connected to the first gate electrode 132. Therefore, a gate signal may be applied to the first gate electrode 132 through the gate line. The gate line may include a material substantially the same as or substantially similar to the first gate electrode 132.

An insulating interlayer 140 may be disposed on the gate insulation layer 130 to cover the first gate electrode 132. The insulating interlayer 140 may include an oxide, a nitride, an oxy-nitride (e.g., SiOxNy) or an organic insulation material.

The first source electrode 152 and the first drain electrode 154 may penetrate the insulating interlayer 140 and the gate insulation layer 130, so that the first source electrode 152 and the first drain electrode 154 may contact the first source region 121 and the first drain region 154, respectively. The first source electrode 152 and the first drain electrode 154 may include a metal (e.g., Al, Cu, Cr), a metal nitride (e.g., TiN), a conductive metal oxide, a transparent conductive material (e.g., ITO, IZo), and the like for example formed as a multi-layered structure.

In example embodiments, a data line disposed on the insulating interlayer 140 may be electrically connected to the first source electrode 152. Therefore, a data signal may be applied to the first source electrode 152 through the data line. The gate line and the data line may intersect at substantially right angles. A pixel region may be defined by the intersection of the gate line and the data line.

The first switching structure of FIG. 3 may include a thin film transistor having a top gate structure, in which the first gate electrode 132 may be disposed above the first semiconductor pattern 120, however the present disclosure of invention may not be limited thereto. For example, the first switching structure may include a thin film transistor having a bottom gate structure, in which a semiconductor pattern may be disposed above the first gate electrode 132. Alternatively, the TFT may include both of upper and lower gate electrodes.

Referring now to FIG. 3, the second switching structure and an internal circuit including signal lines 150 may be disposed in the second region II on the substrate 100. The internal circuit may serve as a circuit for driving the pixels.

In example embodiments, the second switching structure may include a second semiconductor pattern 125, a gate insulation layer 130, a second gate electrode 134, a second source electrode 156, a second drain electrode 158, and the like. The second switching structure may have a constitution substantially the same as or similar to the first switching structure.

Further, the signal lines 150 may be disposed on the insulating interlayer 140. In example embodiments, the signal lines 150 may include a gate line electrically connected to the gate electrodes 132 and 134 of the switching structures and/or a data line electrically connected to the source electrodes 152 and 156.

The power line 160 may be disposed in the third region III (peripheral power line region III) of the substrate 100 and in the same layer as occupied by the signal lines 150, the source and drain electrodes 156, 158 and so on. The power line 160 may supply the low potential pixel power ELVSS to the second electrode 220. In example embodiments, the power line 160 is disposed on the insulating interlayer 140 and extends around at least one side of the second region II. For example, the power line 160 may surround three sides (a top side, a left side and a right side) of the second region II, and may include a gap such that it does not fully surround a bottom side of the second region II as is illustrated in FIGS. 2 and 3. The power line 160 may include a metal (e.g., Al, Cu, Cr), a metal nitride (e.g., TiN), a conductive metal oxide, a transparent conductive material (e.g., ITO, IZo), and the like for example formed as a multi-layered structure. In other words, the power line 160 may be formed using one or more of the same materials as re used for the signal lines 150, the source and drain electrodes 156, 158 and so on. The power line 160 may have either a single layer structure or a multi-layered structure.

An insulation layer 170 may be disposed on the insulating interlayer 140 to cover the source electrodes 152 and 156, the drain electrodes 154 and 158 and the signal lines 150. In example embodiments, the insulation layer 170 may extend from the first region I to the second region II and the third region III. However, the insulation layer 170 may partially cover or may not cover the power line 160 in the third region III. For example, the insulation layer 170 may include a transparent insulation material such as a transparent plastic or a transparent resin.

Referring now to FIG. 3, the first electrode 180 (lower electrode of the OLED 200), a conductive pattern 185 and a pixel area defining pattern 190 may be disposed on the insulation layer 170.

The first electrode 180 may be disposed in the first region I on the insulation layer 170. The first electrode 180 may contact the first drain electrode 154 of the first switching structure through a contact 175 penetrating the insulation layer 170. Therefore, the first electrode 180 may be electrically connected to the first switching structure.

In example embodiments, the first electrode 180 may serve as a pixel electrode that may be patterned corresponding to each pixels, and the first electrode 180 may be an anode that may supply holes to the organic light emitting layer 200.

When the organic light emitting device is a from-the-top emission type, the first electrode 180 may be a reflective or otherwise opaque electrode. On the other hand, the second electrode 220 of the from-the-top emission type OLED should be a transparent electrode or a semi-transparent (e.g., semi-reflective) electrode. When the first electrode 180 is the reflective electrode, the first electrode 180 may include a metal or an alloy that may have a good reflectivity. Light emission may be based on an optical resonance established between the lower, fully reflective first electrode 180 and the upper, partially-reflective, partially-transmissive second electrode 220.

Further, the conductive pattern 185 may be disposed on the insulation layer 170 and the power line 165. In example embodiments, the conductive pattern 185 may directly contact the power line 160 in the third region III (the peripheral power line region III).

The conductive pattern 185 may include a material substantially the same as or substantially similar to that of the first electrode 180. The conductive pattern 185 may include a conductive material of low resistivity, so that the conductive pattern 185 may be electrically connected to the power line 160 without creating any substantial I*R voltage drop.

The pixel defining pattern 190 (e.g., a Black Matrix) may be disposed on the insulation layer 170 and the conductive pattern 185. In the first region I, the pixel defining pattern 190 may be disposed on the insulation layer 170 to partially cover the first electrode 180. That is, the pixel defining pattern 190 may separate each pixels in the first region I, and may prevent a concentration of an electrical potential at end portions of the first electrode 180.

In the second region II and in the third region III, the pixel defining pattern 190 may be disposed on the conductive pattern 185. The pixel defining pattern 190 may entirely cover the conductive pattern 185 in the third region III such that the pixel defining pattern 190 may protect and isolate the conductive pattern 185. While the pixel defining pattern 190 may partially cover the conductive pattern 185 in the second region II. In example embodiments, a plurality of pixel defining patterns 190 may be disposed in the second region II. The plurality of pixel defining patterns 190 may prevent a concentration of an electrical potential at an end portion of the conductive pattern 185.

The auxiliary electrode 210 may be disposed in the second region II (the auxiliary power coupling region II) and on the pixel defining pattern 190 and on the conductive pattern 185. The auxiliary electrode 210 may directly contact the conductive pattern 185 in places where the pixel defining pattern 190 is not be disposed so as to cover the conductive pattern 185. In example embodiments, the auxiliary electrode 210 may be disposed in the second region II adjacent to the power line 160. For example, the auxiliary electrode 210 may be disposed in the second region II that may extend around three sides (a top side, a left side and a right side) of the first region I (the major interior region I).

In example embodiments, the auxiliary electrode 210 may be formed by a vapor deposition process such an evaporation using a conductive metal. For example, the auxiliary electrode 210 may include aluminum, magnesium, silver, platinum, gold, chromium, tungsten, molybdenum, titanium and/or palladium. These may be used alone or combinations thereof. For example, the auxiliary electrode 210 may include an alloy of magnesium and silver in a respective weight ratio of about 9:1.

In other example embodiments, the auxiliary electrode 210 may include a material different from (e.g., having a substantially lower resistivity than) that of the second electrode 220. The auxiliary electrode 210 may directly contact the second electrode 220 and also the conductive pattern 185, so that the auxiliary electrode 210 may include a material that may reduce an interposed contact resistance between the second electrode 220 and the conductive pattern 185.

The auxiliary electrode 210 may be disposed in the second region II, that is the image non-displaying region of the display panel. Accordingly, a non-transparency of the auxiliary electrode 210 will not affect the light efficiency of the organic light emitting display device. Therefore, the material and the thickness of the auxiliary electrode 210 may not be limited to merely transparent or semi-transparent/semi-reflective materials. Moreover, the auxiliary electrode 210 may have a thickness substantially larger than that of the second electrode 220, so that an electrical resistance of the auxiliary electrode 210 may be relatively small and thus a substantial I*R voltage drop is not generated due to presence of the auxiliary electrode 210 in forming part of the inter-layer connection bridge between the power line 160 and the second electrode 220.

In other words, given that the low resistance auxiliary electrode 210 is disposed between the second electrode 220 of higher resistivity and the conductive pattern 185, an electrical resistance therebetween may be decreased as compared to the case where the auxiliary electrode 210 is left out in second region II. Therefore, a substantial I*R voltage drop between the power line 160 and the second electrode 220 may be prevented, and light emission uniformity may be improved.

The second electrode 220 may be disposed conformably and directly on the auxiliary electrode 210 so as to maximize contact area between the two while at the same time conforming to the undulations of the pixel defining pattern 190 in the auxiliary power coupling region II. Additionally, the second electrode 220 may be disposed to oppose the first electrode 180 in the first region I.

In the illustrated example embodiment, the second electrode 220 may serve as a common electrode, and may function as a cathode that may supply electrons to the organic light emitting layer 200.

When the second electrode 220 is a transparent electrode or a semi transparent electrode, the second electrode 220 may include a thin metal layer. In this case, the second electrode 220 may have a predetermined transparency and a predetermined partial reflectivity. If the metallic portion of the second electrode 220 has a relatively large thickness, the transparency of the second electrode 220 may decrease, and the light output efficiency of the organic light emitting device may degrade. Accordingly, the second electrode 220 may have a relatively small thickness below about 30 nm. Particularly, the second electrode 220 may have a thickness of about 10 nm to about 15 nm. The second electrode 220 may include aluminum, magnesium, silver, platinum, gold, chromium, tungsten, molybdenum, titanium or palladium. These may be used alone or combinations thereof. For example, the second electrode 220 may include an alloy of magnesium and silver in a respective weight ratio of about 9:1.

In other example embodiments, the second electrode 220 may include a material substantially the same as or similar to that used in the auxiliary electrode 210. Therefore, the second electrode 220 and a respective part (sublayer) of the auxiliary electrode 210 may be formed integrally.

The organic light emitting layer 200 may be disposed between the first electrode 180 and the second electrode 220. The organic light emitting layer 200 may include at least one light emitting layer. In example embodiments, the organic light emitting layer 200 may include a blue light emitting layer, a green light emitting layer or a red light emitting layer. In other example embodiments, the organic light emitting layer 200 may include the blue light emitting layer, the green light emitting layer and the red light emitting layer which are stacked sequentially. The organic light emitting layer 200 may further include a hole injection layer, a hole transfer layer, an electron injection layer and/or an electron transfer layer.

According to example embodiments, the organic light emitting display device may include the second electrode 220 disposed in the first region I and the second region II, the power line 160 disposed in the third region III and the conductive pattern 185 disposed in the second region II and the third region III. The organic light emitting display device may further include the auxiliary electrode 210 in the second region II to provide bridging between the conductive pattern 185 and the second electrode 220. Therefore, the low potential pixel power ELVSS may be transferred from the power line 160 to the second electrode 220 through the conductive pattern 185 and the auxiliary electrode 210 without incurring current concentration at any one of the plural contacting points between the auxiliary electrode 210 and the conductive pattern 185 and without incurring a substantial I*R voltage drop in the auxiliary power coupling region II. The auxiliary electrode 210 may have a relatively low resistance, so that the voltage drop of the low potential pixel power ELVSS may be reduced. Further, the auxiliary electrode 210 may be disposed in the second region II, and may not disposed in the first region I, so that the light output efficiency of the organic light emitting display device may not be degraded by the presence thereat of the auxiliary electrode 210. Therefore, the light emission uniformity of the organic light emitting display device may be improved.

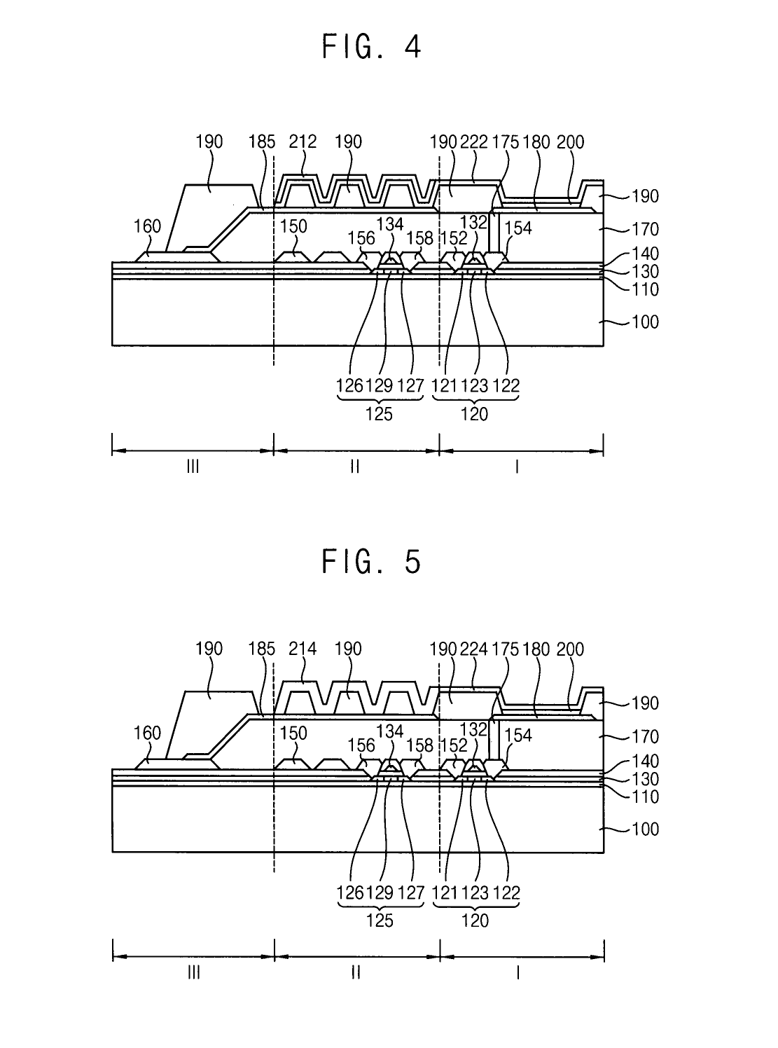

FIG. 4 is a local cross-sectional view illustrating an organic light emitting display device in accordance with another embodiment. The organic light emitting display device of FIG. 4 may be substantially the same as or similar to that illustrated in FIGS. 2 and 3 except for the positioning of the respective auxiliary electrode 212 being on top of rather than below the respective second electrode 222. Thus, like reference numerals refer to like elements, and repetitive explanations thereof may be omitted herein.

Referring to FIG. 4, the organic light emitting display device may include a base substrate 100, first and second switching structures, a first electrode 180, an organic light emitting layer 200, a second electrode 222, a conductive pattern 185 and a power line 160. The organic light emitting display device may be divided into a first region I (major interior region I), a second region II (auxiliary power coupling region II) and a third region III (peripheral power line region III).

A buffer layer 110, the first and second switching structures, an insulating interlayer 140 and signal lines 150 may be disposed on the substrate 100, and an insulation layer 170 may be disposed to cover the above mentioned components. In example embodiments, the insulation layer 170 may extend from the first region I to the second region II and the third region III. Further, the power line 160 in the third region III may not entirely be covered with the insulation layer 170.

A first electrode 180 may be disposed in the first region I on the insulation layer 170, and a conductive pattern 185 may be disposed in the second region II and the third region III on the insulation layer 170.

When the organic light emitting display device is of a top emission type, the first electrode 180 may be a reflective electrode including a metal or an alloy having a relatively large reflectivity. The conductive pattern 185 may directly contact the power line 160, and may include a material substantially the same as that of the reflective, metallic first electrode 180.

Further, the pixel defining patterns 190 may be disposed on the insulation layer 170 to partially cover the first electrode 180 and the conductive pattern 185.

The second electrode 222 may be disposed on the pixel defining patterns 190 and the conductive pattern 185. The second electrode 222 may be disposed to oppose the first electrode 180 in the first region I, and may be disposed on the conductive pattern 185 and the pixel defining pattern 190 in the second region II.

When the second electrode 222 is a transparent electrode or a semi-transparent, semi-reflective electrode, the second electrode 222 may include a metal. The second electrode 222 may include a material substantially the same as or similar to that of the second electrode 220 described with reference to FIGS. 2 and 3.

The auxiliary electrode 212 may be disposed in the second region II and on top of the second electrode 222. In example embodiments, the auxiliary electrode 212 may include a material substantially the same as or similar to one used for the second electrode 222.

According to the example embodiment of FIG. 4, the organic light emitting display device may include the auxiliary electrode 212 in the second region II on the second electrode 222. Therefore, the low potential pixel power ELVSS may be transferred from the power line 160 to the second electrode 222 through the conductive pattern 185 and the auxiliary electrode 212. The auxiliary electrode 212 may have a relatively low resistance, so that the voltage drop of the low potential pixel power ELVSS may be reduced.

FIG. 5 is a local cross-sectional view illustrating an organic light emitting display device in accordance with yet another embodiment. The organic light emitting display device of FIG. 5 may be substantially the same as or similar to those illustrated with reference to FIGS. 2 and 3 except for the respective auxiliary electrode 214 of FIG. 5 which is a thicker but monolithically integral extension of the second electrode 224. Thus, like reference numerals refer to like elements, and repetitive explanations thereon may be omitted herein.

Referring to FIG. 5, the organic light emitting display device may include a substrate 100, first and second switching structures, a first electrode 180, an organic light emitting layer 200, a second electrode 224, a conductive pattern 185 and a power line 160. The organic light emitting display device may be divided into a first region I, a second region II and a third region III.

A buffer layer 110, the first and second switching structures, an insulating interlayer 140 and signal lines 150 may be disposed on the substrate 100, and an insulation layer 170 may be disposed to cover the above mentioned components. In example embodiments, the insulation layer 170 may extend from the first region I to the second region II and the third region III. Further, the power line 160 in the third region 160 may not be entirely covered with the insulation layer 170.

A first electrode 180 may be disposed in the first region I on the insulation layer 170, and a conductive pattern 185 may be disposed in the second region II and the third region III on the insulation layer 170.

The conductive pattern 185 may directly contact the power line 160, and may include a material substantially the same as that of the first electrode 180. The conductive pattern 185 may electrically connect the power line 160 and also at distributed contact points with the illustrated auxiliary electrode 214.

The pixel defining patterns 190 may be disposed on the insulation layer 170 to partially cover the first electrode 180 and the conductive pattern 185.

The second electrode 224 may be disposed in the first region I on the pixel defining patterns 190. The second electrode 224 may be disposed to oppose the first electrode 180. The second electrode 224 may include a material substantially the same as or similar to that of the second electrode 220 described with reference to FIGS. 2 and 3.

The auxiliary electrode 214 may be disposed in the second region II on the conductive pattern 185 and the pixel defining pattern 190. In example embodiment of FIG. 5, the auxiliary electrode 214 uses a material substantially the same as or similar to that of the second electrode 224 except that it has greater thickness. Alternatively, the auxiliary electrode 214 may additionally include a material different from that of the second electrode 224. The auxiliary electrode 214 may have a thickness at least twice the thickness, if not more, of the second electrode 224.

According to example embodiments, the organic light emitting display device may include the auxiliary electrode 214 in the second region II on the conductive pattern 185 and the pixel defining pattern 190. Therefore, the low potential pixel power ELVSS may be transferred from the power line 160 to the second electrode 224 through the conductive pattern 185 and the auxiliary electrode 214. The auxiliary electrode 214 may have a relatively low resistance, so that the voltage drop of the low potential pixel power ELVSS may be reduced.

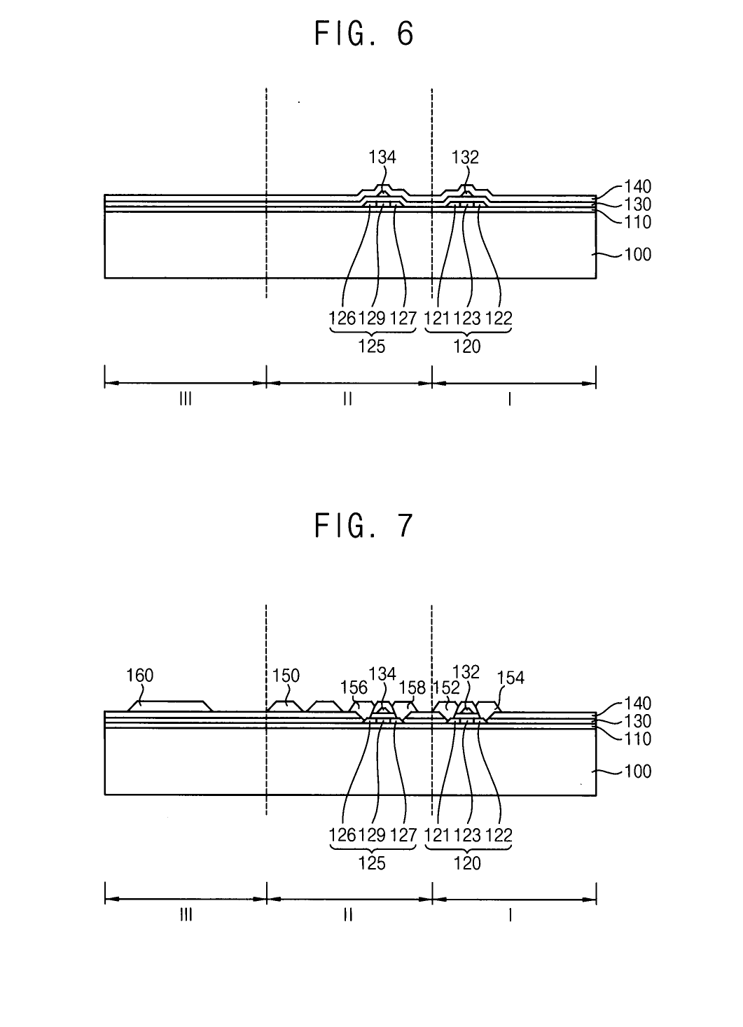

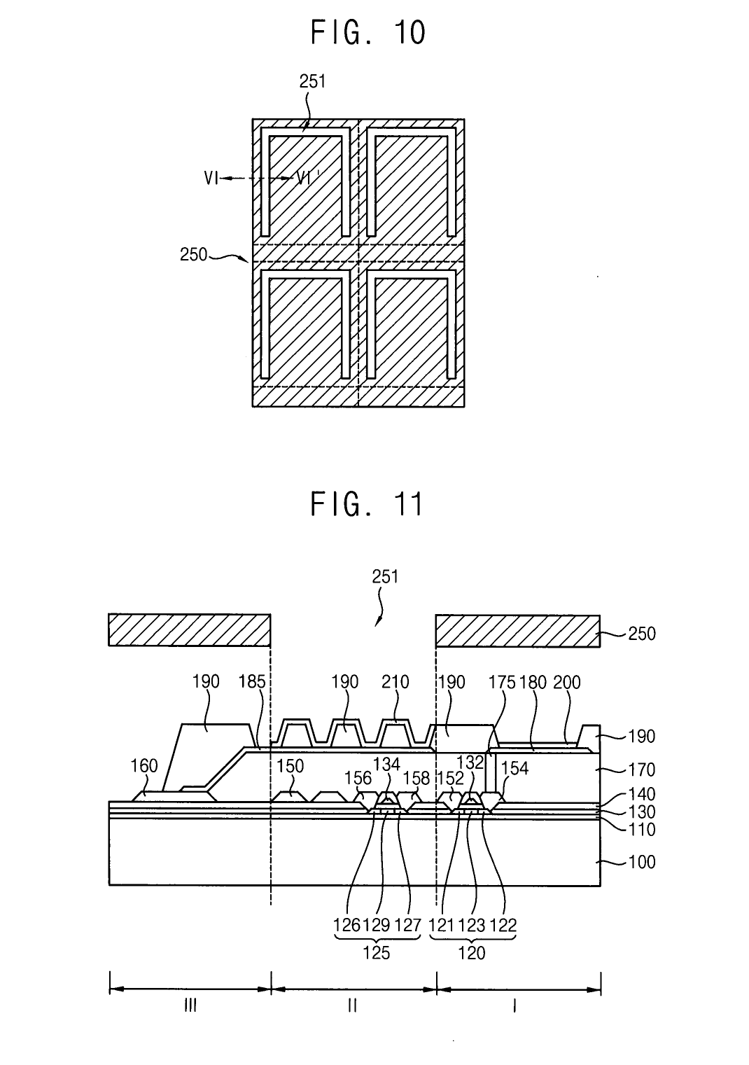

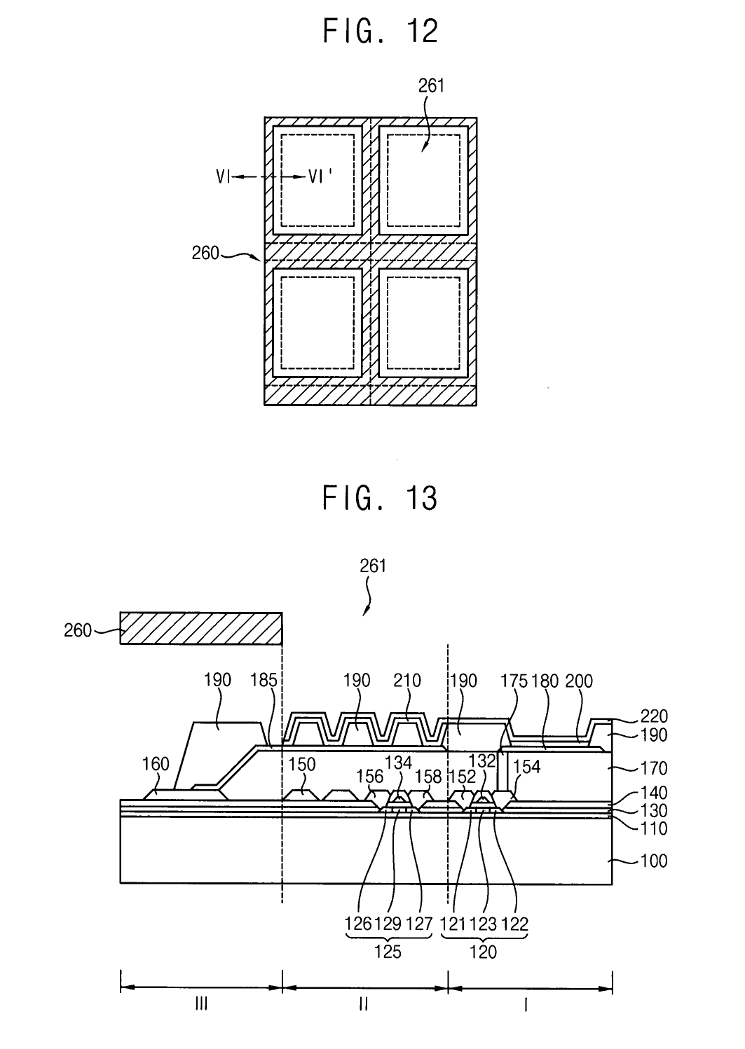

FIGS. 6 to 13 include plan views and cross-sectional views illustrating a method of manufacturing an organic light emitting display device in accordance with some of the embodiments described above. FIGS. 6, 7, 8, 9, 11 and 13 are cross-sectional views illustrating a method of manufacturing an organic light emitting display device in accordance with some embodiments, and FIGS. 10 and 12 are plan views illustrating a mask used for manufacturing an organic light emitting display device.

Referring to FIG. 6, a buffer layer 110, semiconductor patterns 120 and 125, a gate insulation layer 130, gate electrodes 132 and 134 and an insulating interlayer 140 may be formed on a substrate 100.

The substrate 100 may be divided into a first region I, a second region II and a third region III in accordance with FIG. 2. The buffer layer 110 may be formed on the substrate 100, and a semiconductor layer may be formed on the buffer layer 110. The semiconductor layer may be partially removed, and impurities may be implanted into the semiconductor layer to form the semiconductor patterns 120 and 125. In example embodiments, the semiconductor layer may be formed using polysilicon, doped polysilicon, amorphous silicon or doped amorphous silicon. In other example embodiments, the semiconductor layer may be formed using a ternary system or a quaternary system, semiconductive oxide comprising a combination of AwBxCyO (A, B, C—Zn, Cd, Ga, In, Sn, Hf or Zr; 0≦w, x, y). Impurities may be implanted into the first semiconductor pattern 120, thereby forming a first source region 121 and a first drain region 122 and defining a first channel region 123 therebetween. Further, impurities may be implanted into the second semiconductor pattern 125, thereby forming a second source region 126 and a second drain region 127 and defining a second channel region 129 therebetween.

Then, the gate insulation layer 130 may be formed on the buffer layer 110 to cover the semiconductor patterns 120 and 125. The gate electrodes 132 and 134 and insulating interlayer 140 may be formed on the gate insulation layer 130.

Referring to FIG. 7, source electrodes 152 and 156, drain electrodes 154 and 158, a signal line 150 and a power line 160 may be formed on the insulating interlayer 140 using one or more low resistivity conductive materials for the same.

The gate insulation layer 130 and the insulating interlayer 140 may be partially removed to form openings exposing the source regions 121 and 123 and the drain regions 122 and 127, and a first conductive layer may be formed on the insulating interlayer 140 to fill the openings. Then, the first conductive layer may be partially removed to form the first source electrode 152 and the first drain electrode 154 in the first region I, the second source electrode 156, the second drain electrode 158 and the signal line 150 in the second region II, and the power line 160 in the third region III.

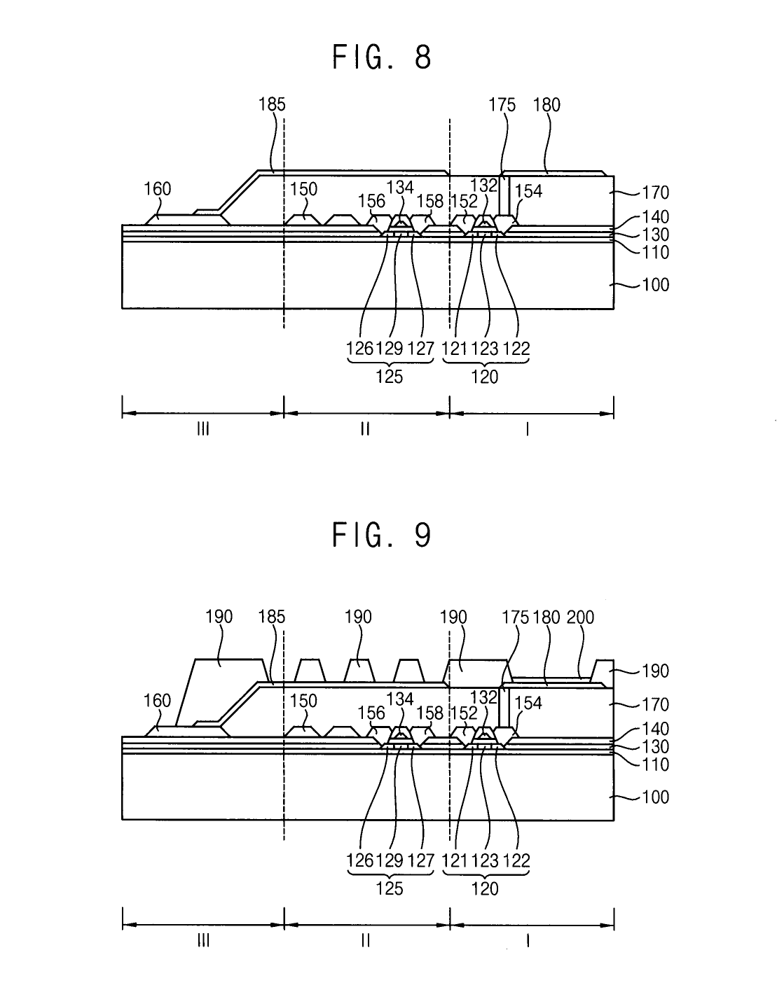

Referring to FIG. 8, an insulation layer 170 may be formed on the insulating interlayer 140 and planarized so as to cover the source electrodes 152 and 156, the drain electrodes 154 and 158 and the signal line 150 while providing an essentially planar top surface. A first electrode 180 and a conductive pattern 185 may be formed on the insulation layer 170 simultaneously after drain contact hole 175 is formed.

The insulation layer 170 may extend from the first region I to the second region II and the third region III, and may partially cover or may not cover the power line 160.

Then, a second conductive layer may be formed on the insulation layer 170 and the power line 160, and the second conductive layer may be patterned to form the first electrode 180 in the first region I and the conductive pattern 185 in the second region II and the third region III. In this case, the conductive pattern 185 may be electrically connected to the power line 160 as shown in FIG. 8.

In addition, and as mentioned, a first contact hole 175 may be formed through the insulation layer 170 before forming the first electrode 180. Therefore, the first contact hole 175 may provide electrical connection between the first drain electrode 154 with the first electrode 180.

Referring to FIG. 9, next, a pixel defining pattern 190 may be formed to cover the first electrode 180 and the conductive pattern 185, and then an organic light emitting layer 200 may be formed on the first electrode 180.

The pixel defining pattern 190 may be formed using a light blocking insulation material (e.g., a dyed photoresist). In example embodiments, a plurality of pixel defining patterns 190 may be formed in the first region I, the second region II and the third region III. The pixel defining pattern 190 may be formed to cover end portions of the first electrode 180 to separated each pixels in the first region I. Further, the pixel defining pattern 190 may protect the conductive pattern 185 and the power line 160 in the third region III.

Referring to FIGS. 10 and 11, an auxiliary electrode 210 may be formed to cover the pixel defining pattern 190 and the conductive pattern 185 by using a first mask 250 exposing the second region II.

The first mask 250 may include a first opening 251. The first opening 251 may partially expose the second region II of the substrate 100. In example embodiments, the first opening 251 may expose portions of the second region II that surround three sides (a top side, a left side and a right side) of the first region I.

In example embodiments, the first mask 250 may include a plurality of first openings 251 and each of the first openings 251 may correspond to each of the organic light emitting display devices.

The auxiliary electrode 210 may be formed by a physical vapor deposition process. For example, the auxiliary electrode 210 may be formed by an evaporation process or a sputtering process using the first mask 250.

In example embodiments, the auxiliary electrode 210 may be formed by an evaporation process in which a silver source and a magnesium source may be heated simultaneously. In this case, a crucible for receiving the silver source and the magnesium source may be disposed at a lower portion of a vacuum chamber, and the substrate 100 may be disposed at an upper portion of the vacuum chamber. The first mask 250 may be arranged to expose the second region II of the substrate 100. Alternatively, the auxiliary electrode 210 may be formed by a co-sputtering process using a silver target and a magnesium target.

Referring to FIGS. 12 and 13, a second electrode 220 may be formed to cover the auxiliary electrode 210, the pixel defining pattern 190 and the organic light emitting layer 200 by using a second mask 260 exposing the first region I and the second region II during the deposition process.

The second mask 260 may include a second opening 261. The second opening 261 may entirely expose the first region I and the second region II of the substrate 100. In example embodiments, the second mask 260 may include a plurality of second openings 261.

The process for forming the second electrode 220 may be substantially similar to the process for forming the auxiliary electrode 210 except for the second mask 260.

In example embodiments, the second mask 220 may be formed by an evaporation process using the silver source and the magnesium source. Therefore, the second mask 220 and the auxiliary electrode 210 may be formed in the same vacuum chamber by using the same evaporation source. Alternatively, the second electrode 220 may be formed by using an evaporation source different from those of the auxiliary electrode 210.

According to example embodiments, the auxiliary electrode 210 having a relatively low resistance may be formed in the second region II between the conductive pattern 185 and the second electrode 220. Therefore, voltage drop from the conductive pattern 185 to the second electrode 220 may be reduced.

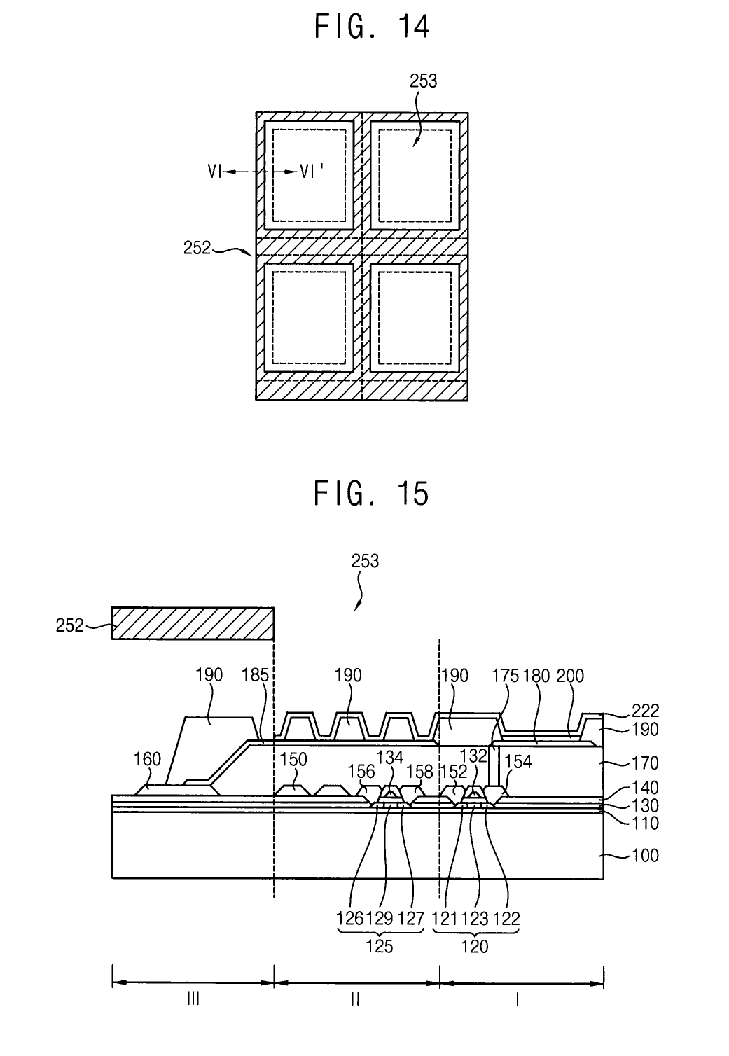

FIGS. 14 to 17 are plan views and cross-sectional views illustrating a method of manufacturing an organic light emitting display device in accordance with other embodiments.

First, processes substantially the same as or similar to those illustrated with reference to FIGS. 6 to 9 may be performed. That is, first and second switching structures, a power line 160, a first electrode 180 and a pixel defining pattern 190 may be formed on a substrate 100.

Referring to FIGS. 14 and 15, a second electrode 222 may be formed first to cover the conductive pattern 185, the pixel defining pattern 190 and the organic light emitting layer 200 by using a first mask 252 exposing the first region I and the second region II.

The first mask 252 may include a first opening 253, and the first opening 253 may entirely expose the first region I and the second region II of the substrate 100. Process for forming the second electrode 222 may be substantially similar to those of the second electrode 220 described with reference to FIGS. 12 and 13.

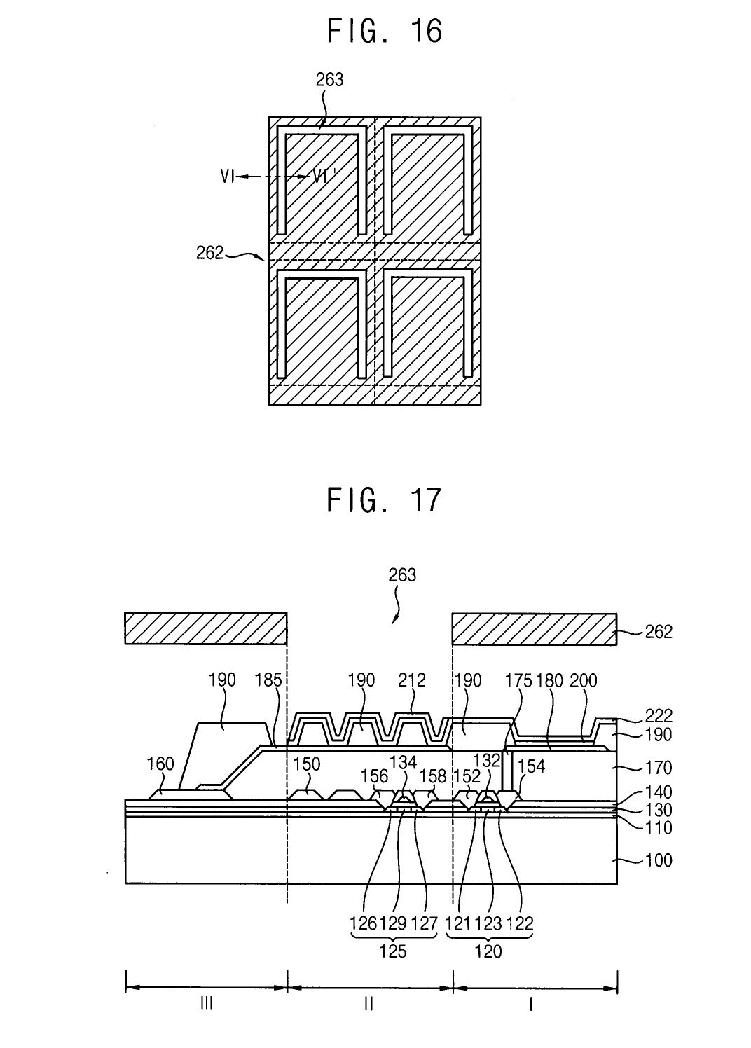

Referring to FIGS. 16 and 17, an auxiliary electrode 212 may thereafter be formed on top of the second electrode 22 by using a second mask 262 exposing the second region II.

The second mask 262 may include a second opening 263, and the second opening 263 may partially expose the second region II of the substrate 100. Process for forming the auxiliary electrode 212 may be substantially similar to those of the auxiliary electrode 210 described with reference to FIGS. 10 and 11.

According to example embodiments, even though a position of the auxiliary electrode 212 and the second electrode 222 are changed, the auxiliary electrode 212 having a relatively low resistance may be formed in the second region II on the second electrode 222. Therefore, a voltage drop from the conductive pattern 185 to the second electrode 222 may be reduced.

FIGS. 18 to 21 are plan views and cross-sectional views illustrating a method of manufacturing an organic light emitting display device in accordance with yet other embodiments.

First, processes substantially the same as or similar to those illustrated with reference to FIGS. 6 to 9 may be performed. That is, first and second switching structures, a power line 160, a first electrode 180 and a pixel defining pattern 190 may be formed on a substrate 100.

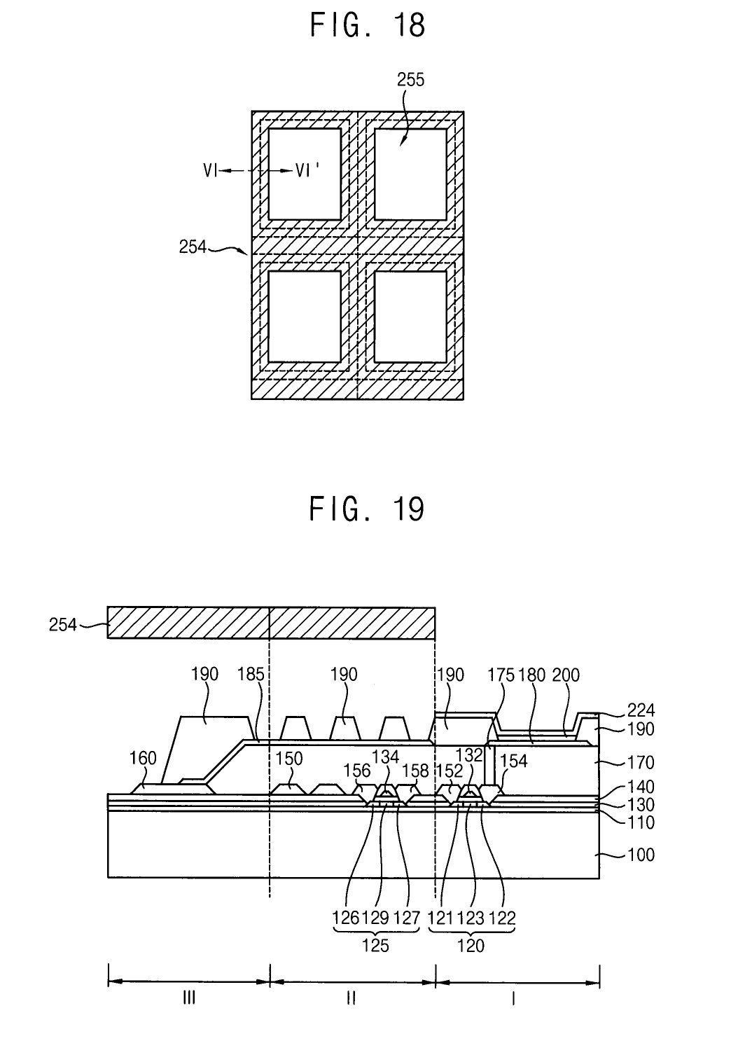

Referring to FIGS. 18 and 19, a second electrode 224 may be formed to cover the pixel defining pattern 190 and the organic light emitting layer 200 by using a first mask 254 exposing the first region I.

The first mask 254 may include a first opening 255, and the first opening 255 may entirely expose the first region I of the substrate 100. In example embodiments, the first mask 254 may include a plurality of first openings 255 as shown in FIG. 18. Process for forming the second electrode 224 may be substantially similar to those of the second electrode 220 described with reference to FIGS. 12 and 13.

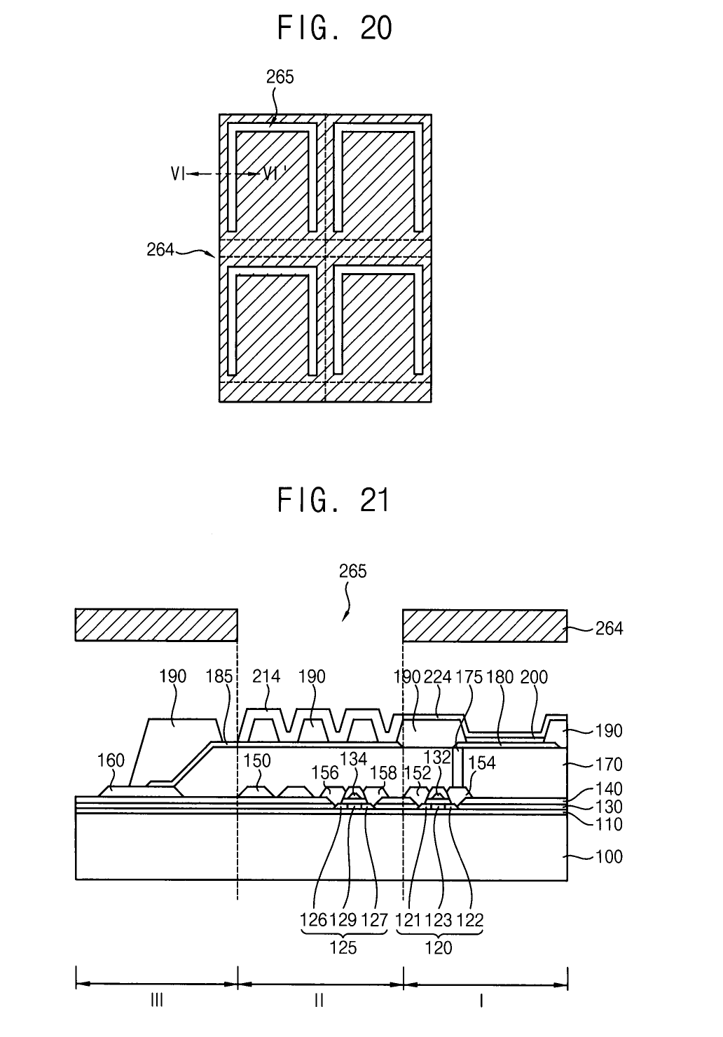

Referring to FIGS. 20 and 21, an auxiliary electrode 214 may be formed on the conductive pattern 185 and the pixel defining pattern 190 by using a second mask 264 exposing the second region II.

The second mask 264 may include a second opening 265, and the second opening 265 may partially expose the second region II of the substrate 100. Process for forming the auxiliary electrode 214 may be substantially similar to those of the auxiliary electrode 210 described with reference to FIGS. 10 and 11.

According to example embodiments, even though positions of the auxiliary electrode 214 and the second electrode 224 are changed, the auxiliary electrode 214 having a relatively low resistance may be formed between the second electrode 224 and the conductive pattern 185. Therefore, a voltage drop from the conductive pattern 185 to the second electrode 224 may be reduced.

Given the here provided, example embodiments, the inventive concept may be applied to various other electric apparatuses. For example, the inventive concept may be applied to not only in a stationary electric apparatus such as a monitor, a television, a digital information display (DID) apparatus, but also in a portable electric apparatus such as a notebook, a digital camera, a mobile phone, a smart phone, a smart pad, a personal digital assistant (PDA), a personal media player (PMP), a MP3 player, a navigation system, a camcorder, a portable game machine, and the like.

The foregoing is illustrative of example embodiments and is not to be construed as limiting thereof. Although a few example embodiments have been described, those skilled in the art will readily appreciate in view of the foregoing that many modifications are possible in the example embodiments without materially departing from the novel teachings and advantages of the here disclosed inventive concepts. Accordingly, all such modifications are intended to be included within the scope of the present teachings. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the disclosure.

What is claimed is:

1. An organic light emitting display device, comprising:
a substrate having a first region (region I), a second region (region II) and a third region (region III), the second region (II) extending at least partially around the first region, and the third region (III) extending at least partially around the second region;
a first electrode and a light emitting structure coupled to be driven by the first electrode both disposed in the first region (I) and on the substrate;
a power line disposed in the third region (III) and on the substrate;
a second electrode provided on and coupled to the light emitting structure so as to oppose the first electrode, the second electrode being disposed at least in the first region (I) of the substrate;
a conductive pattern electrically connecting the second electrode with the power line; and
an auxiliary electrode directly contacting the second electrode, the auxiliary electrode being disposed in the second region (II) of the substrate;
wherein the auxiliary electrode has a lower resistivity per unit area than that of the second electrode.

2. The organic light emitting display device of claim 1, wherein the auxiliary electrode has a thickness substantially larger than a thickness of the second electrode.

3. The organic light emitting display device of claim 1, wherein the auxiliary electrode includes a material substantially the same as a material used in the second electrode.

4. The organic light emitting display device of claim 1, wherein the auxiliary electrode entirely covers a top surface of a portion of the second electrode in the second region.

5. The organic light emitting display device of claim 1, wherein the second electrode entirely covers a top surface of the auxiliary electrode in the second region.

6. The organic light emitting display device of claim 1, wherein the second electrode includes an alloy of magnesium and silver in a respective weight ratio of about 9:1.

7. The organic light emitting display device of claim 1, wherein the power line extends around at least three sides of the second region (II).

8. The organic light emitting display device of claim 1, further comprising a pixel defining pattern disposed between the second electrode and the conductive pattern in the second region,
wherein the pixel defining pattern covers end portions of the conductive pattern.

9. The organic light emitting display device of claim 1, wherein the first region is an image displaying region containing the light emitting structure, and wherein the second region and the third region are non-displaying regions.

10. A method of manufacturing an organic light emitting display device, the method comprising:
providing a substrate having a first region (region I), a second region (region II) and a third region (region III), the second region (II) extending at least partially around the first region, and the third region (III) extending at least partially around the second region;
forming a power line in the third region and on the substrate;
forming a first electrode and a conductive pattern simultaneously, the first electrode being disposed in the first region of the substrate;
forming a light emitting structure on the first electrode;
forming an auxiliary electrode electrically connected to the conductive pattern in the second region by performing a deposition process using a first mask; and
forming a second electrode coupled to the light emitting structure and opposing the first electrode by performing a deposition process using a second mask, the second electrode being disposed in the first region of the substrate and being electrically connected to the auxiliary electrode.

11. The method of claim 10, wherein the first mask is arranged to partially expose the second region of the substrate, and wherein the second mask is arranged to expose the first region and the second region of the substrate.

12. The method of claim 10, wherein the deposition processes using the first mask and the second mask include a physical vapor deposition process that deposits its vapor materials through respective openings of the respective masks.

13. The method of claim 12, wherein a process for forming the auxiliary electrode and a process for forming the second electrode are performed in the same chamber using the same source gas.

14. The method of claim 10, wherein the power line extends around at least three sides of the second region.

15. The method of claim 10, wherein the auxiliary electrode has a thickness substantially larger than a thickness of the second electrode.

16. The method of claim 10, further comprising forming a pixel defining pattern in the second region, before forming the light emitting structure.

17. The method of claim 10, wherein the first region is an image displaying region that contains the light emitting structure, and wherein the second region and the third region are non-displaying regions.
